(19) United States
(12) Patent Application Publication
(10) Pub. No.: US 2016/0260537 A1
(43) Pub. Date: Sep. 8, 2016

(54) TRANSFORMER BASED LCTANK STRUCTURE

(71) Applicant: Realtek Semiconductor Corp., Hsinchu (TW)

(72) Inventors: Hsiao-Tsung YEN, Hsin Chu City (TW); Chih-Yu TSAI, Hsin Chu City (TW)

(21) Appl. No.: 14/821,207

(22) Filed: Aug. 7, 2015

(30) Foreign Application Priority Data
Mar. 2, 2015 (TW) 104106437

(51) Int. Cl. H01F 27/28; H01F 27/42; H03K 17/56; H01F 27/40; H01F 27/29; H01F 41/06

(52) U.S. Cl. CPC H01F 27/2823; H01F 27/29; H01F 41/06; H03K 17/56; H01F 27/40; H01F 27/42

(57) ABSTRACT

A transformer includes a first winding and a second winding. The first winding is constructed in a preset solid region having a first level and a second level. The first winding is wound from a first end in a left side region of the first level, guided across a first center line and through a right side region of the second level, and wound in a left side region of the second level until reaches a second end in the left side region of the second level. The second winding is wound from a first end in the right side region of the second level, guided across the first center line and through the left side region of the second level, and wound in a right side region of the first level until reaches a second end in the right side region of the first level.

### BACKGROUND

a. Field of the Invention

The invention relates generally to an electronic device and, more particularly, to a transformer for an oscillator and a winding method for the transformer.

b. Description of the Related Art

FIG. 1 shows a schematic diagram of a conventional transformer. The transformer may be a four-terminal device having two inductors, where a primary winding does not cross a secondary winding to omit a DC block.

However, the construction of windings shown in FIG. 1 may cause asymmetry in inductance, and thus integrating the transformer into a differential circuit may be more difficult. Besides, in situations where such a transformer is integrated into an oscillator circuit, a capacitor needs to be additionally provided to increase layout areas and fabrication costs.

Therefore, it is desirable to give inductance symmetry for the primary winding and the secondary winding and to reduce layout areas of a capacitor.

### BRIEF SUMMARY OF THE INVENTION

The invention relates, in one embodiment, to a transformer for an oscillator having reduced occupied space.

The invention relates, in one embodiment, to a transformer for an oscillator having improved inductance symmetry.

The invention relates, in one embodiment, to an oscillator based on a transformer having reduced occupied space.

According to an embodiment of the invention, a transformer for an oscillator includes a first winding and a second winding. The first winding is a first planar metal winding and constructed in a preset solid region. The preset solid region includes a first level and a second level, and each of the first level and the second level includes a left side region and a right side region. The first winding is wound from a first end in the left side region of the first level, guided across a first center line and through the right side region of the second level, and wound in the left side region of the second level until reaches a second end in the left side region of the second level. The second winding is a second planar metal winding and constructed in the preset solid region. The second winding is wound from a first end in the right side region of the second level, guided across the first center line and through the left side region of the second level, and wound in the right side region of the first level until reaches a second end in the right side region of the first level. The first winding has a first center tap disposed along a second center line and in the right side region of the second level, and the second winding has a second center tap disposed along the second center line and in the left side region of the second level.

According to another embodiment of the invention, a winding method for a transformer used with an oscillator includes the following steps. First, a first winding and a second winding are wound in a preset solid region. The preset solid region may include a first level and a second level, each of the first level and the second level may include a left side region and a right side region. The first winding is wound from a first end in the left side region of the first level, guided across a first center line and through the right side region of the second level, and wound in the left side region of the second level until reaches a second end in the left side region of the second level. The second winding is wound from a first end in the right side region of the second level, guided across the first center line and through the left side region of the second level, and wound in the right side region of the first level until reaches a second end in the right side region of the first level. The first winding is provided with a first center tap disposed along a second center line and in the right side region of the second level, and the second winding is provided with a second center tap disposed along the second center line and in the left side region of the second level.

In order to form an oscillator or provide additional functionalities, the first end in the left side region of the first level and the first end in the right side region of the second level may be coupled to a power source, a switch or a capacitor, the first center tap and the second center tap may be coupled to a voltage source, a switch or a capacitor, and the second end in the left side region of the second level and the second end in the right side region of the first level may be coupled to a power source, a switch or a capacitor.

According to the above embodiments, the first winding and the second winding are interlaced and stacked with each other to achieve inductance symmetry and reduce occupied space for the first winding and the second winding. Further, the center taps are disposed in a center space of the windings without the use of additional metal layers, and a capacitor or other device may be also disposed in the center space to further reduce the entire occupied space. Besides, the transformer may combine with a switch or other device to form an oscillator having a broad tuning range and enhanced circuit design flexibility.

### BRIEF DESCRIPTION OF THE DRAWINGS

FIG. 1 shows a schematic diagram of a conventional transformer.

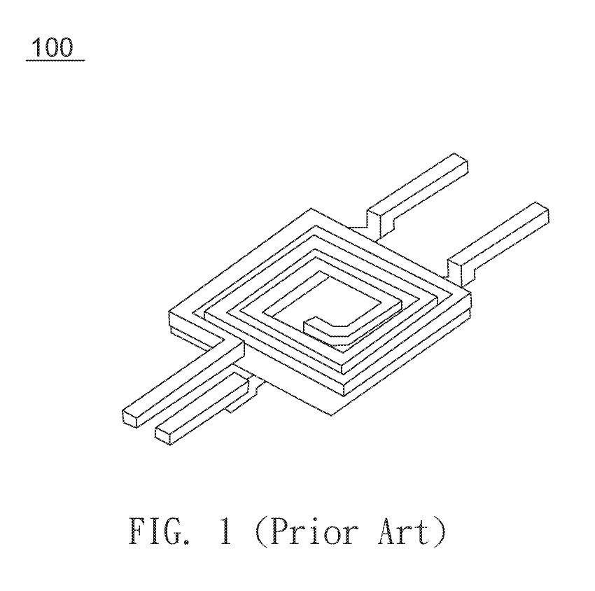

FIG. 2A shows schematic diagrams of a transformer for an oscillator according to an embodiment of the invention, where a plan view is shown on the left side and a perspective view is shown on the right side of FIG. 2A.

FIG. 2B shows a schematic diagram illustrating an exemplified structure of the first winding.

FIG. 2C shows a schematic diagram illustrating an exemplified structure of the second winding.

FIG. 3 shows an example of an LC tank oscillator using the transformer shown in FIG. 2A and an equivalent circuit diagram of the LC tank oscillator.

FIG. 4 schematically shows a circuit design used with a transformer according to an embodiment of the invention.

FIG. 5 schematically shows a circuit design used with a transformer according to another embodiment of the invention.

FIG. 6 schematically shows a circuit design used with a transformer according to another embodiment of the invention.

FIG. 7 shows a flow chart illustrating a winding method for a transformer used with an oscillator according to an embodiment of the invention.

### DETAILED DESCRIPTION OF THE INVENTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

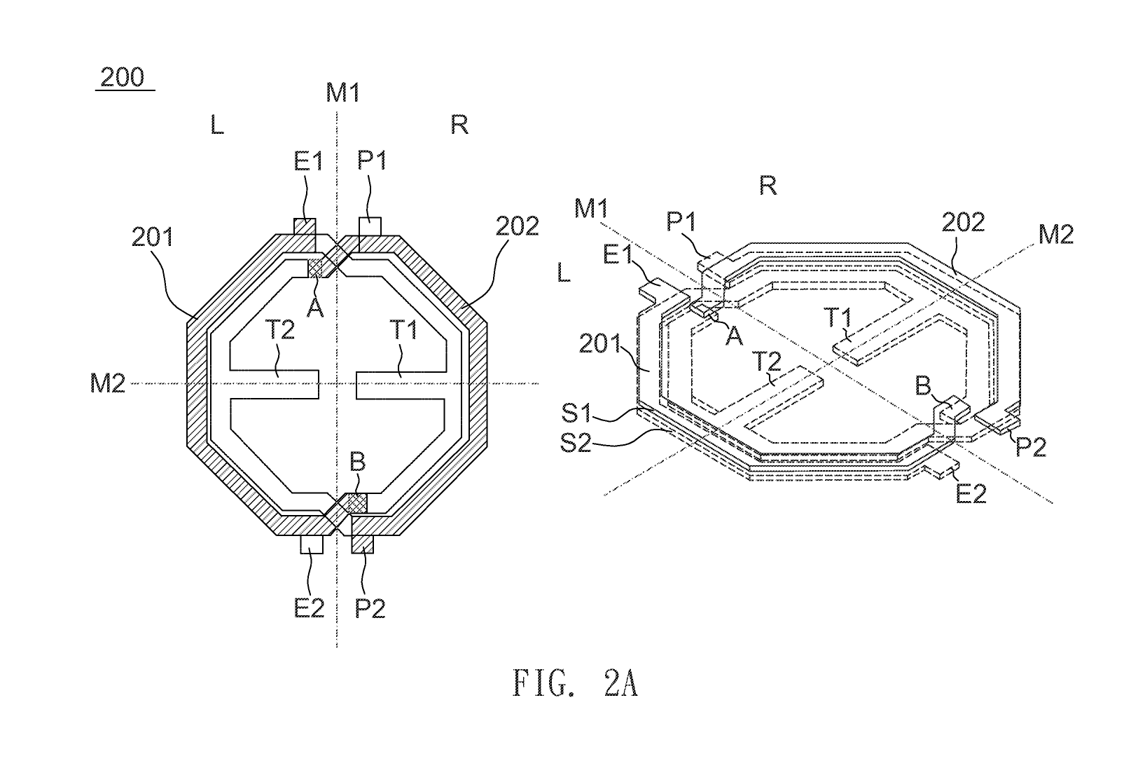

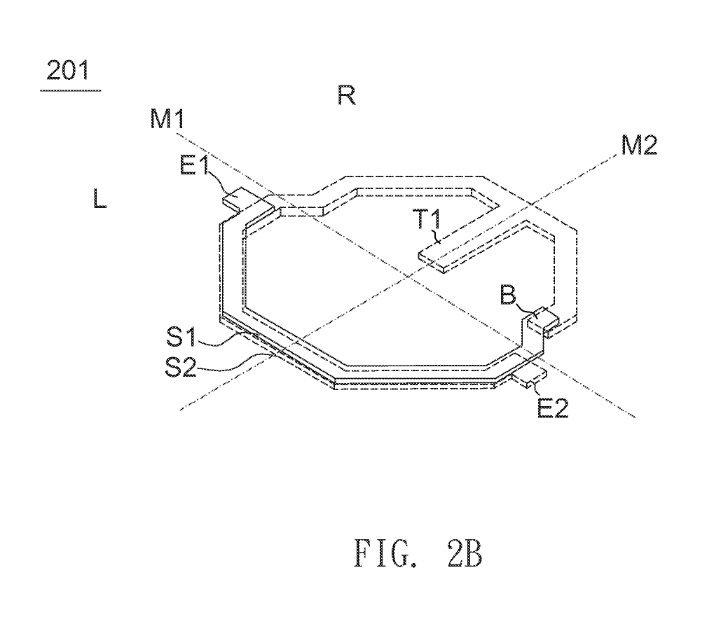

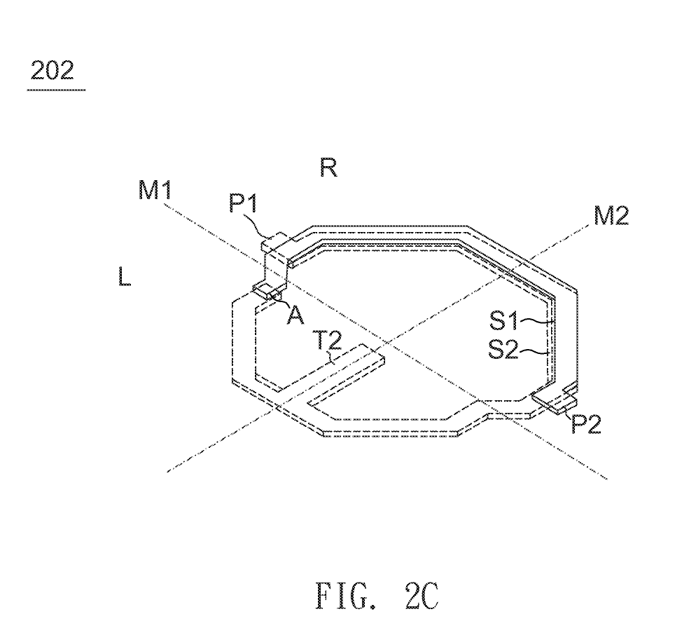

FIG. 2A shows schematic diagrams of a transformer for an oscillator according to an embodiment of the invention, where a plan view is shown on the left side and a perspective view is shown on the right side of FIG. 2A.

The transformer 200 includes a first winding 201 and and a second winding 202.

The first winding 201 is a first planar metal winding and constructed in a preset solid region. The preset solid region may include a first level S1 and a second level S2, and each of the first level S1 and the second level S2 includes a left side region L and a right side region R. The first planar metal winding is wound from a first end E1 in the left side region L of the first level S1, guided across a first center line M1 and through the right side region R of the second level S2, and wound in the left side region L of the second level S2 until reaches a second end E2 in the left side region L of the second level S2.

The second winding 202 is a second planar metal winding and constructed in the preset solid region. The second planar metal winding is wound from a first end P1 in the right side region R of the second level S2, guided across the first center line M1 and through the left side region L of the second level S2, and wound in the right side region R of the first level S1 until reaches a second end P2 in the right side region R of the first level S1.

The first winding 201 has a first center tap T1 disposed along a second center line M2 and in the right side region R of the second level S2. The second winding 202 has a second center tap T2 disposed along the second center line M2 and in the left side region L of the second level S2. In one embodiment, the first center line M1 is substantially perpendicular to the second center line M2.

Note, after the first winding 201 is wound from the first end E1 in the left side region L of the first level S1 and guided across the first center line M1, the first winding 201 is further wound in the right side region R of the second level S2 via a connection point B and finally reaches the second end E2 in the left side region L of the second level S2. Besides, after the second winding 202 is wound from a first end P1 in the right side region R of the second level S2 and guided across the first center line M1 and through the left side region L of the second level S2, the second winding 202 is further wound in the right side region R of the first level S1 via a connection point A and finally reaches a second end P2 in the right side region R of the first level S1.

FIG. 2B shows a schematic diagram illustrating an exemplified structure of the first winding 201, and FIG. 2C shows a schematic diagram illustrating an exemplified structure of the second winding 202. As illustrated in FIG. 2B, the first winding 201 is wound in the left side region L of the first level S1 to form one-half turn, and then the first winding 201 is wound in the right side region R and the left side region L of the second level S2 via the connection point B to form one turn. Therefore, a sum of 1.5 turns of the first winding 201 is achieved.

As illustrated in FIG. 2C, the second winding 202 is wound in the right side region R and the left side region L of the second level S2 to form one turn, and then the second winding 202 is wound in the right side region R of the first level S1 via the connection point A to form one-half turn. Therefore, a sum of 1.5 turns of the second winding 202 is achieved.

According to the above embodiment, the first winding 201 and the second winding 202 are interlaced and stacked with each other (1.5 turns of the first winding 201 plus 1.5 turns of the second winding 202) to achieve inductance symmetry for the first winding 201 and the second winding 202. Further, the center taps T1 and T2 are disposed in a center space of the windings 201 and 202 to provide additional functionalities, reduce occupied space, and save fabrication costs.

Another applications of the transformer according to an embodiment of the invention are described below.

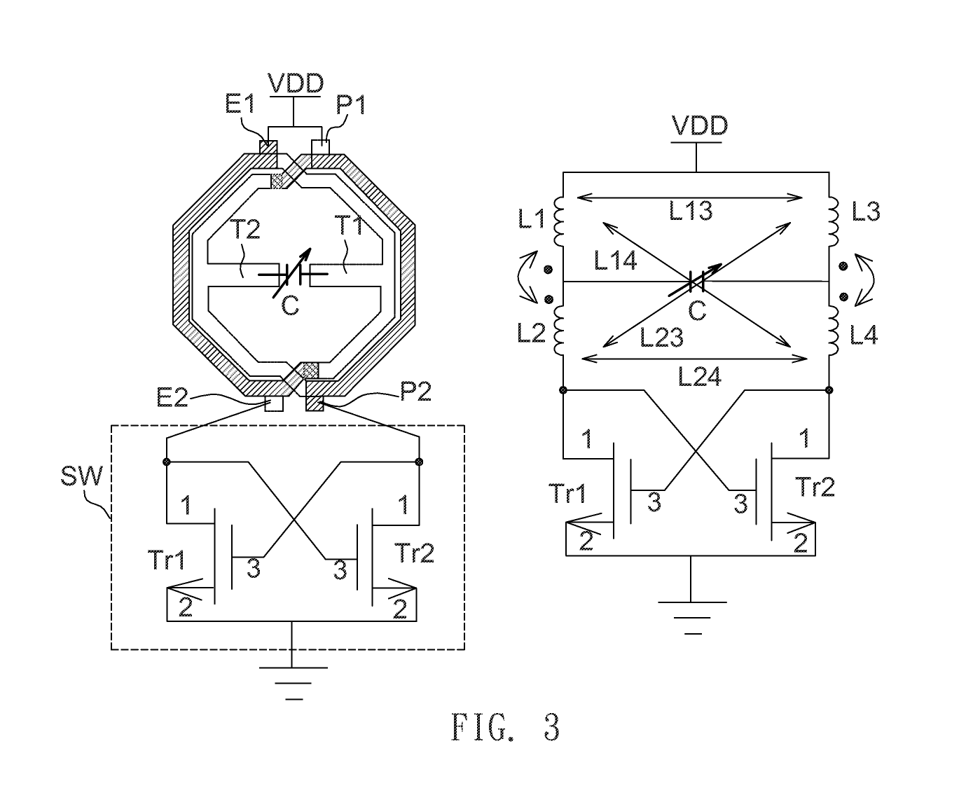

FIG. 3 shows an example of an LC tank oscillator using the transformer shown in FIG. 2A and an equivalent circuit diagram of the LC tank oscillator. As illustrated in FIG. 3A, a power source VDD is coupled to the first end E1 in the left side region L of the first level S1 and the first end P1 in the right side region R of the second level S2. The first center tap T1 and the second center tap T2 are coupled to two terminals of a variable capacitor C. A switch SW is coupled to the second end E2 in the left side region L of the second level S2 and the second end P2 in the right side region R of the first level 51. The switch SW may include a first transistor Tr1 and a second transistor Tr2. A first terminal 1 of the first transistor Tr1 is coupled to the second end E2 in the left side region L of the second level S2, and a second terminal 2 of the first transistor Tr1 is grounded. A first terminal 1 of the second transistor Tr2 is coupled to the second end P2 in the right side region R of the first level S1, a second terminal 2 of the second transistor Tr2 is grounded, a control terminal 3 of the second transistor Tr2 is coupled to the first terminal 1 of the first transistor Tr1, and a control terminal 3 of the first transistor Tr1 is coupled to the first terminal 1 of the second transistor Tr2. The equivalent circuit diagram of the LC tank oscillator is illustrated on the right side of FIG. 3. Note, in an alternate embodiment, the ground level may be replaced by other voltage level.

According to the above embodiment, a variable capacitor C can be disposed in the center of a transformer (center of an inductor) to provide self inductances L1, L2, L3 and L4, mutual inductances L13, L14, L23 and L24, and oscillations for a capacitor to hence reduce layout areas of a chip and to form center taps without the use of additional metal layers. Besides, the first winding 201 and the second winding 202 are interlaced and stacked with each other to reduce occupied space and layout areas of a chip.

Further, the transformer 200 may combine with a switch or other device to serve other function or broaden a tuning range.

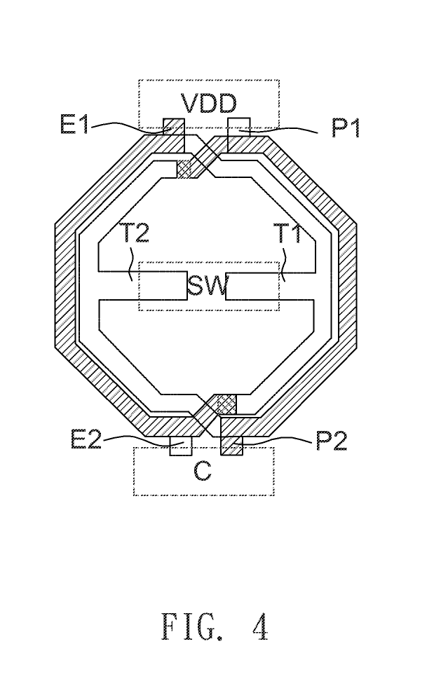

In one embodiment as illustrated in FIG. 4, a power source VDD is coupled to the first end E1 in the left side region L of the first level S1 and the first end P1 in the right side region R of the second level S2. A switch SW is coupled to the first center tap T1 and the second center tap T2. Note the switch SW may be, but not limited to, in the form of a structure shown in FIG. 3, and the switch SW may be in the form of other structure compatible with a wide variety of existing and future designs. A capacitor C is coupled to the second end E2 in the left side region L of the second level S2 and the second end P2 in the right side region R of the first level S1. In one embodiment, the capacitor C may be a variable capacitor. According to the above embodiment, an oscillator circuit based on the transformer 200 may have a wider tuning range or at least two sets of oscillation frequencies. For a high-frequency oscillator, only a small variable capacitor is required, but a small variable capacitor is influenced by parasitic capacitances to a greater extent to result in a narrow tuning range. Under the circumstance, the tuning range needs to be broadened, and it is the case that the switch SW is disposed in the center space according to this embodiment to reduce layout areas of a device used to broaden the tuning range.

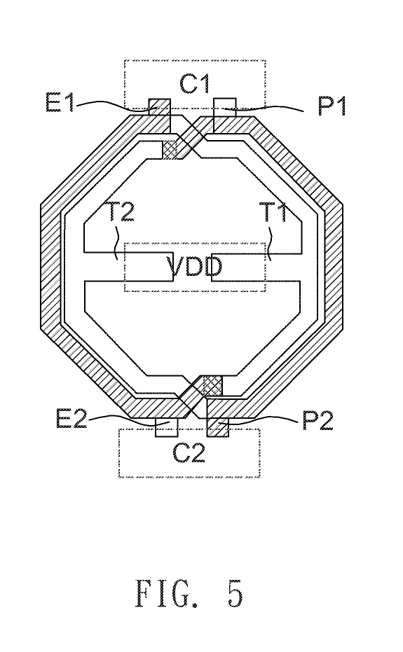

In one embodiment as illustrated in FIG. 5, a first capacitor C1 is coupled to the first end E1 in the left side region L of the first level S1 and the first end P1 in the right side region R of the second level S2. The first center tap T1 and the second center tap T2 are coupled to a power source VDD. A second capacitor C2 is coupled to the second end E2 in the left side region L of the second level S2 and the second end P2 in the right side region R of the first level S1. In one embodiment, the capacitors C1 and C2 may be variable capacitors. According to this embodiment, an oscillator circuit based on the transformer 200 may form two capacitors arranged in symmetry and two LC tank oscillators, and the layout areas can be also reduced.

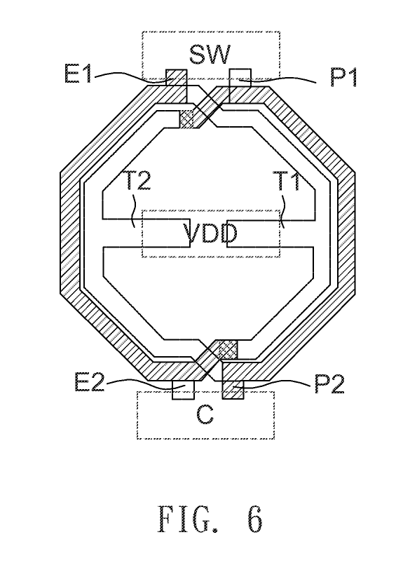

In one embodiment as illustrated in FIG. 6, a switch SW is coupled to the first end E1 in the left side region L of the first level S1 and the first end P1 in the right side region R of the second level S2. Note the switch SW may be, but not limited to, in the form of a structure shown in FIG. 3, and the switch SW may be in the form of other structure compatible with a wide variety of existing and future designs. The first center tap T1 and the second center tap T2 are coupled to a power source VDD. A capacitor C is coupled to the second end E2 in the left side region L of the second level S2 and the second end P2 in the right side region R of the first level S1. In one embodiment, the capacitor C may be a variable capacitor. According to the this embodiment, an oscillator circuit based on the transformer 200 may switch between two different oscillation frequencies and is more symmetry to open the possibility that pads may be disposed in an area indicated by the label VDD shown in FIG. 6 to save the layout areas of pads.

Note the number of turns of the first winding and the second winding includes, but is not limited to, 1.5. For example, the number of turns may be 2.5, 3.5, 4.5, and so forth.

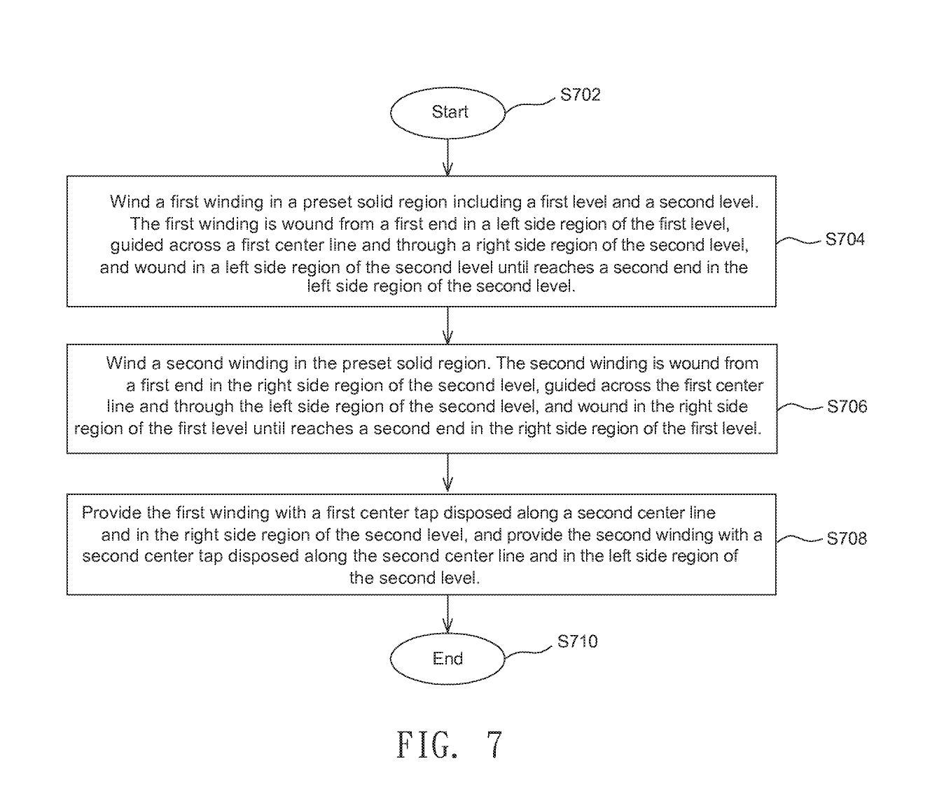

FIG. 7 shows a flow chart illustrating a winding method for a transformer used with an oscillator according to an embodiment of the invention. The winding method may include the following steps.

Step S702: Start.

Step S704: Wind a first winding in a preset solid region. The preset solid region may include a first level and a second level, each of the first level and the second level may include a left side region and a right side region. The first winding is wound from a first end in the left side region of the first level, guided across a first center line and through the right side region of the second level, and wound in the left side region of the second level until reaches a second end in the left side region of the second level.

Step S706: Wind a second winding in the preset solid region. The second winding is wound from a first end in the right side region of the second level, guided across the first center line and through the left side region of the second level, and wound in the right side region of the first level until reaches a second end in the right side region of the first level.

Step S708: Provide the first winding with a first center tap disposed along a second center line and in the right side region of the second level, and provide the second winding with a second center tap disposed along the second center line and in the left side region of the second level.

Step S710 End.

In order to form an oscillator or provide additional functionalities, the first end in the left side region of the first level and the first end in the right side region of the second level may be coupled to a power source, a switch or a capacitor, the first center tap and the second center tap may be coupled to a voltage source, a switch or a capacitor, and the second end in the left side region of the second level and the second end in the right side region of the first level may be coupled to a power source, a switch or a capacitor.

According to the above embodiments, the first winding and the second winding are interlaced and stacked with each other to achieve inductance symmetry and reduce occupied space for the first winding and the second winding. Further, the center taps are disposed in a center space of the windings without the use of additional metal layers, and a capacitor or other device may be also disposed in the center space to further reduce the entire occupied space. Besides, the transformer may combine with a switch or other device to broaden a tuning range.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A transformer for an oscillator, comprising:
a first winding being a first planar metal winding and constructed in a preset solid region, the preset solid region comprises a first level and a second level, each of the first level and the second level includes a left side region and a right side region, wherein the first winding is wound from a first end in the left side region of the first level, guided across a first center line and through the right side region of the second level, and wound in the left side region of the second level until reaches a second end in the left side region of the second level; and
a second winding being a second planar metal winding and constructed in the preset solid region, the second winding being wound from a first end in the right side region of the second level, guided across the first center line and through the left side region of the second level, and wound in the right side region of the first level until reaches a second end in the right side region of the first level; wherein
the first winding has a first center tap disposed along a second center line and in the right side region of the second level, and the second winding has a second center tap disposed along the second center line and in the left side region of the second level.

2. The transformer as claimed in claim 1, wherein the first end in the left side region of the first level and the first end in the right side region of the second level are coupled to a power source.

3. The transformer as claimed in claim 2, further comprising:
a variable capacitor having two terminals respectively coupled to the first center tap and the second center tap.

4. The transformer as claimed in claim 3, wherein the second end in the left side region of the second level and the second end in the right side region of the first level are coupled to a switch.

5. The transformer as claimed in claim 3, wherein the switch comprises:
a first transistor, wherein a first terminal of the first transistor is coupled to the second end in the left side region of the second level, and a second terminal of the first transistor is grounded; and
a second transistor, wherein a first terminal of the second transistor is coupled to the second end in the right side region of the first level, a second terminal of the second transistor is grounded, a control terminal of the second transistor is coupled to the first terminal of the first transistor, and a control terminal of the first transistor is coupled to the first terminal of the second transistor.

6. The transformer as claimed in claim 5, wherein the first center tap and the second center tap are coupled to a switch.

7. The transformer as claimed in claim 6, wherein the switch comprises:
a first transistor, wherein a first terminal of the first transistor is coupled to the second center tap, and a second terminal of the first transistor is grounded; and
a second transistor, wherein a first terminal of the second transistor is coupled to the first center tap, a second terminal of the second transistor is grounded, a control terminal of the second transistor is coupled to the first terminal of the first transistor, and a control terminal of the first transistor is coupled to the first terminal of the second transistor.

8. The transformer as claimed in claim 7, wherein the second end in the left side region of the second level and the second end in the right side region of the first level

9. The transformer as claimed in claim 1, wherein the first end in the left side region of the first level and the first end in the right side region of the second level are coupled to a first capacitor.

10. The transformer as claimed in claim 9, wherein the first center tap and the second center tap are coupled to a power source.

11. The transformer as claimed in claim 10, wherein the second end in the left side region of the second level and the second end in the right side region of the first level are coupled to a second capacitor.

12. The transformer as claimed in claim 1, wherein the first end in the left side region of the first level and the first end in the right side region of the second level are coupled to a switch.

13. The transformer as claimed in claim 12, wherein the switch comprises:
a first transistor, wherein a first terminal of the first transistor is coupled to the first end in the left side region of the first level, and a second terminal of the first transistor is grounded; and
a second transistor, wherein a first terminal of the second transistor is coupled to the first end in the right side region of the second level, a second terminal of the second transistor is grounded, a control terminal of the second transistor is coupled to the first terminal of the first transistor, and a control terminal of the first transistor is coupled to the first terminal of the second transistor.

14. The transformer as claimed in claim 13, wherein the first center tap and the second center tap are coupled to a power source.

15. The transformer as claimed in claim 14, wherein the second end in the left side region of the second level and the second end in the right side region of the first level are coupled to a variable capacitor.

16. A winding method for a transformer used with an oscillator, comprising the steps of:
winding a first winding in a preset solid region, wherein the preset solid region comprises a first level and a second level, each of the first level and the second level includes a left side region and a right side region, the first winding is wound from a first end in the left side region of the first level, guided across a first center line and through the right side region of the second level, and wound in the left side region of the second level until reaches a second end in the left side region of the second level;
winding a second winding in the preset solid region, wherein the second winding is wound from a first end in the right side region of the second level, guided across the first center line and through the left side region of the second level, and wound in the right side region of the first level until reaches a second end in the right side region of the first level; providing the first winding with a first center tap disposed along a second center line and in the right side region of the second level; and
providing the second winding with a second center tap disposed along the second center line and in the left side region of the second level.

17. The method as claimed in claim 16, further comprising:
coupling the first end in the left side region of the first level and the first end in the right side region of the second level to a power source, a switch or a capacitor.

18. The method as claimed in claim 16, further comprising:
coupling the first center tap and the second center tap to a voltage source, a switch or a capacitor.

19. The method as claimed in claim 16, further comprising:
coupling the second end in the left side region of the second level and the second end in the right side region of the first level to a power source, a switch or a capacitor.
